(19) United States
(12) Patent Application Publication
(10) Pub. No.: US 2021/0202784 A1
(43) Pub. Date: Jul. 1, 2021

(54) APPARATUS FOR MANUFACTURE OF A SOLAR CELL ARRANGEMENT HAVING TWO OR MORE OVERLAPPING SOLAR CELL PIECES, SYSTEM FOR MANUFACTURE OF A SOLAR CELL ARRANGEMENT, AND METHOD FOR ASSEMBLING A SOLAR CELL ARRANGEMENT

(71) Applicant: APPLIED MATERIALS ITALIA S.R.L., San Biagio di Callalta (IT)

(72) Inventor: Marco GALIAZZO, Padova (pd) (IT)

(21) Appl. No.: 16/092,814

(22) PCT Filed: Sep. 28, 2017
(86) PCT No.: PCT/EP2017/074657

§ 371 Date: Oct. 11, 2018

(51) Int. Cl. H01L 31/18; H01L 31/05

(52) U.S. Cl. CPC H01L 31/188; H01L 31/0516

(57) ABSTRACT

The present disclosure provides an apparatus for manufacture of a solar cell arrangement having two or more overlapping solar cell pieces. The apparatus includes a positioning device configured to selectively adjust an overlap of adjacent solar cell pieces based on a predetermined length of the solar cell arrangement.

### FIELD

Embodiments of the present disclosure relate to an apparatus for manufacture of a solar cell arrangement having two or more overlapping solar cell pieces, a system for manufacture of a solar cell arrangement, and a method for assembling a solar cell arrangement. Embodiments of the present disclosure particularly relate to an apparatus, system and method for the manufacture of shingled solar cells.

### BACKGROUND

Solar cells are photovoltaic devices that convert sunlight directly into electrical power. An efficiency of the solar cells can be affected by an active area on a front surface 20 of the solar cell which is exposed to light for converting sunlight into electrical power. The active area can be reduced due to the presence of electrical contacts, such as fingers and/or busbars, on the front surface of the solar cells. The presence of the electrical contacts on the front surface of the solar cells can thus reduce a module power of a solar cell module consisting of the solar cells.

Shingled solar cell arrangements can increase an output power of a solar cell module. The increase in the output power can be affected by a quality of a manufacturing process, such as a quality of the elements used to assemble the shingled solar cell arrangement. Further, a proper assembling of the shingled solar cell arrangement can be cumbersome, and a throughput and/or yield can be low.

In view of the above, new apparatuses for the manufacture of a solar cell arrangement having two or more overlapping solar cell pieces, systems for the manufacture of a solar cell arrangement, and methods for assembling a solar cell arrangement, that overcome at least some of the problems in the art are beneficial. The present disclosure particularly aims at improving the manufacturing process of solar cell arrangements, such as shingled solar cells.

### SUMMARY

In light of the above, an apparatus for the manufacture of a solar cell arrangement having two or more overlapping solar cell pieces, a system for the manufacture of a solar cell arrangement, and a method for assembling a solar cell arrangement are provided. Further aspects, benefits, and features of the present disclosure are apparent from the claims, the description, and the accompanying drawings.

According to an aspect of the present disclosure, an apparatus for the manufacture of a solar cell arrangement having two or more overlapping solar cell pieces is provided. The apparatus includes a positioning device configured to selectively adjust an overlap of adjacent solar cell pieces based on a predetermined length of the solar cell arrangement.

According to a further aspect of the present disclosure, an apparatus for the manufacture of a solar cell arrangement having two or more overlapping solar cell pieces is provided. The apparatus includes a positioning device configured to provide an essentially constant distance between edges of adjacent solar cell pieces, wherein the distance is defined between an edge of a second solar cell piece overlapping a first solar cell piece and an edge of the first solar cell piece not overlapping the second solar cell piece.

According to another aspect of the present disclosure, a system for the manufacture of a solar cell arrangement is provided. The system includes the apparatus for the manufacture of a solar cell arrangement having two or more overlapping solar cell pieces according to the embodiments described herein, a production tool for manufacturing a plurality of solar cells, and a separation device configured to separate the plurality of solar cells into solar cell pieces.

According to a further aspect of the present disclosure, a method for assembling a solar cell arrangement is provided. The method includes a positioning of a first solar cell piece on a support device, and an overlapping of a second solar cell piece with the first solar cell piece. An overlap of the first solar cell piece and the second solar cell piece is determined based on a predetermined length of the solar cell arrangement.

According to a yet further aspect of the present disclosure, a method for assembling a solar cell arrangement is provided. The method includes a positioning of a first solar cell piece on a support device, and an overlapping of a second solar cell piece with the first solar cell piece. An essentially constant distance is provided between an edge of the second solar cell piece overlapping the first solar cell piece and an edge of the first solar cell piece not overlapping the second solar cell piece.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic view of an apparatus for the manufacture of a solar cell arrangement according to embodiments described herein;

FIG. 2A shows schematic views of a shingled solar cell manufactured using the apparatuses, systems and methods according to the embodiments described herein;

FIG. 2B shows a schematic view of overlapping solar cell pieces according to the embodiments described herein;

FIG. 3 shows a schematic top view of a separation device according to embodiments described herein;

FIGS. 4A and B show schematic views of a full-square solar cell and a pseudo-square solar cell, respectively, according to embodiments described herein;

FIG. 5A shows a schematic side view of an apparatus for the manufacture of a solar cell arrangement according to further embodiments described herein;

FIG. 5B shows a schematic top view of an apparatus for manufacture of a solar cell arrangement according to yet further embodiments described herein;

FIG. 5C shows a schematic view of overlapping solar cell pieces on a support device according to embodiments described herein;

FIG. 6 show schematic views of a positioning device according to embodiments described herein;

FIG. 7 shows a schematic view of an apparatus for the manufacture of at least two solar cell arrangements according to embodiments described herein;

FIG. 8 shows a schematic view of a system for the manufacture of a solar cell arrangement according to embodiments described herein; and

FIG. 9 shows a flow chart of a method for assembling a solar cell arrangement according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

The solar cell arrangements of the present disclosure can be shingled solar cells, which can also be referred to as “hypercells” or “supercells”. The solar cell arrangements can be used in solar cell modules. The solar cell arrangements can be made of a plurality of partially overlapping solar cell pieces (also referred to as “solar cell elements”). Adjacent solar cell pieces are electrically connected to each other in the overlapping region. The solar cell pieces are connected in series such that current generated by the individual solar cell pieces flows along the series of solar cell pieces to be collected, for example, at an end portion of the solar cell arrangement. The overlapping configuration can provide high-efficiency solar cell modules. In particular, the solar cell arrangements allow for increasing a module power by increasing a used or active area. Typically, the overlapping configuration can increase the module power by, for example, 20 to 40 Watts. The used or active area can correspond to an area that is irradiated by solar light and that participates in the generation of power. For example, the used or active area can correspond to an area of the solar cells that is not covered by, for example, conductive line patterns, such as fingers and/or busbars.

An overlap of adjacent solar cell pieces defines a length of the solar cell arrangement, such as a solar cell string. Manufacturing tolerances may lead to solar cell pieces having slightly different dimensions, affecting the length of the solar cell arrangement. For example, solar cell arrangements may have different lengths depending on the dimensions of the solar cell pieces used to manufacture the solar cell arrangements.

The embodiments of the present disclosure individually adjusts a relative positioning of two adjacent solar cell pieces. In particular, an overlap of adjacent solar cell pieces is individually adjusted and/or an essentially constant distance between edges of the adjacent solar cell pieces is provided. For example, a 2-point algorithm for an alignment of adjacent solar cell pieces with a nominal overlap can be used. In such a 2-point alignment, only three sides of the solar cell piece are used, and two corners defined for X and Y coordinates. Basically no information about the fourth side is necessary, which could be used to calculate the shingle width and define the correct overlap. Metrology can be simplified by doing edge distance control because the measurements to calculate placement precision along the string direction and placement angle can be measured by looking at one side of the string only and not at both sides. Solar cell arrangements having a predetermined length, i.e., a defined length or set length, can be manufactured. A difference in string lengths depending on shingle dimensions can be reduced or even avoided. Further, a constant cell area exposed to sunlight for all solar cell pieces (shingles) and essentially the same short circuit current Isc for the solar cell arrangement in a series connection can be provided.

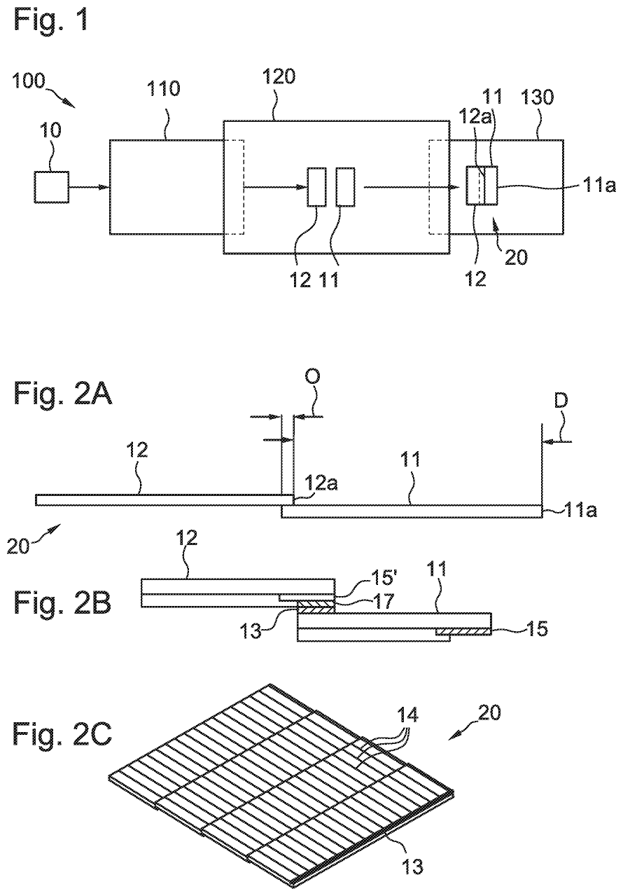

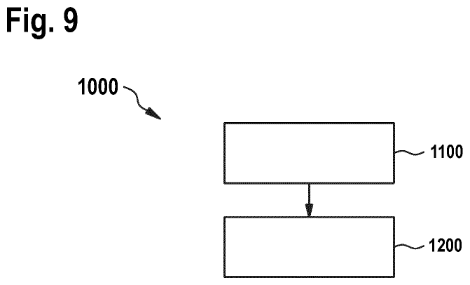

FIG. 1 shows a schematic view of an apparatus 100 for the manufacture of at least one solar cell arrangement having two or more overlapping solar cell pieces according to embodiments described herein. The apparatus 100 can be part of a larger production line, as it is for example described with respect to FIG. 9.

The apparatus 100 includes a positioning device 120. The positioning device 120 is configured to do at least one of (i) selectively adjusting an overlap of adjacent solar cell pieces, such as a first solar cell piece 11 and a second solar cell piece 12, based on a predetermined (or set) length of the solar cell arrangement 20, and (ii) providing an essentially constant distance between edges of the adjacent solar cell pieces. The distance is defined between an edge 12a of the second solar cell piece 12, the edge 12a of which overlaps the first solar cell piece 11, and an edge 11a of the first solar cell piece 11, the edge of which does not overlap the second solar cell piece 12. The edges can be essentially parallel to each other.

The term “selectively adjusting an overlap” is to be understood in the sense that the overlap is individually determined or adjusted for at least one pair of adjacent solar cell pieces of the solar cell arrangement 20, and specifically for each pair of adjacent solar cell pieces of the solar cell arrangement 20. At least some of the overlaps or overlap areas in the solar cell arrangement 20 can be different, i.e., not constant.

The length of the solar cell arrangement 20 can correspond to a (final) length or extension of the (finished) solar call arrangement having a number of N solar cell pieces. The solar cell arrangement 20 can have the length and a width, wherein the width of the solar cell arrangement can correspond to a width (“first extension”, “major extension” or “long edge”) of the individual solar cell pieces. The length of the solar cell arrangement can correspond to a sum of the lengths of all solar cell pieces (“second extension”, “minor extension” or “short edge”) minus the sum of the overlaps.

The term “essentially constant distance” is to be understood in the sense that the respective distances of all pairs of adjacent solar cell pieces of the solar cell arrangement can be essentially equal to each other. The term “essentially” relates to an essentially constant distance (or equal distances for the pairs) between the edges, wherein a small deviation, e.g., 1%, 2%, or even 5% due to a positioning accuracy and/or manufacturing tolerances from a perfectly constant distance is still considered as “essentially constant.”

According to some embodiments, which can be combined with other embodiments described herein, a solar cell arrangement, such as a shingled solar cell, can include two or more solar cell pieces. Although FIG. 1 exemplarily illustrates two solar cell pieces, it is to be understood that the present disclosure is not limited thereto and that the solar cell arrangement can include, or consist of, a number of N solar cell pieces, wherein N is an integer greater than 0. For example, N can be at least 10, specifically at least 20, specifically at least 30, specifically at least 40, and more specifically at least 50.

According to some embodiments, which can be combined with other embodiments described herein, the apparatus 100 includes a separation device 110 configured for separating a solar cell 10 into two or more solar cell pieces, such as the first solar cell piece 11 and the second solar cell piece 12 used to manufacture the solar cell arrangement 20. In some implementations, the apparatus 100 includes a support device 130 configured to support the two or more overlapping solar cell pieces. The positioning device 120 can be configured to position the two or more solar cell pieces on the support device 130 such that the adjacent solar cell pieces overlap.

In some implementations, the solar cell 10 which is divided into the two or more solar cell pieces can have one or more conductive patterns, such as fingers and/or busbars, provided thereon. In particular, the term “solar cell” can refer to a finished or nearly finished solar cell as opposed to, for example, an unprocessed semiconductor substrate. The solar cell 10 can have a frontside and a backside. Fingers and/or busbars can be deposited on the frontside, for example, using a printing technique such as screen printing. Optionally, the solar cell 10 can have one or more backside contacts.

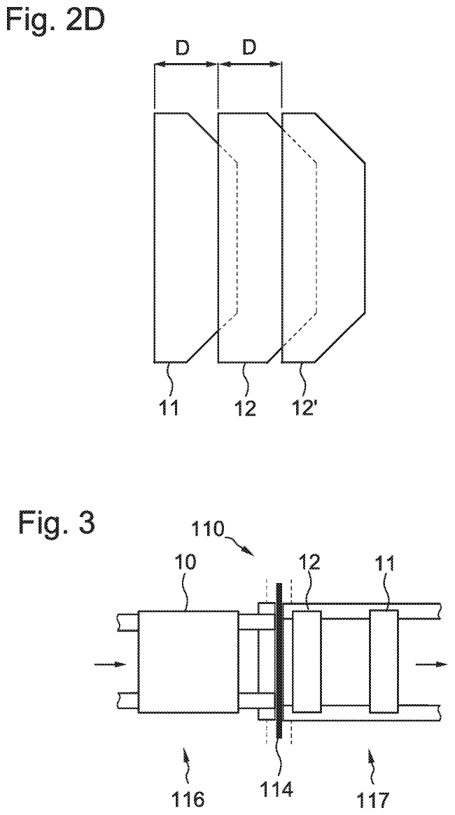

FIG. 2A shows a schematic view of a solar cell arrangement 20 which can be manufactured using the apparatuses, systems and methods according to the embodiments described herein. The solar cell arrangement 20 can be used in a solar cell module, which a packaged, connected assembly of a plurality of solar cells or solar cell arrangements.

The shingled solar cell includes a plurality of overlapping solar cell pieces, such as the first solar cell piece 11 and the second solar cell piece 12. The overlap O of adjacent solar cell pieces can be less than 20%, specifically less than 10%, and more specifically less than 5% of the total surface area, such as the frontside surface or backside surface, of the solar cell pieces.

In some implementations, each solar cell piece of the plurality of overlapping solar cell pieces of the solar cell arrangement 20 can have one or more conductive patterns, such as fingers 14 and/or busbars 13, provided thereon. For example, the solar cell piece, such as the first solar cell piece 11, can have a frontside and a backside corresponding to the frontside and the backside, respectively, of the former solar cell. Optionally, the solar cell piece can have one or more backside contacts. As exemplarily shown in FIG. 2A, the first solar cell piece 11 can have a backside contact 15, and the second solar cell piece 12 can have a backside contact 15′.

Adjacent solar cell pieces are electrically connected to each other in the overlapping region. The solar cell pieces are thus connected in series such that current generated by the individual solar cell pieces flows along the series of solar cell pieces to be collected, for example, at an end portion of the solar cell arrangement 20 (not shown). The overlapping configuration can provide solar cell arrangements having an increased output power. For example, the busbar 13 provided on the first solar cell piece 11 can be electrically connected to the backside contact 15′ of the second solar cell piece 12. As shown in the example of FIG. 2A, the separation device can be configured to separate the solar cell adjacent to the busbars of the solar cell. In other words, each solar cell piece can have a busbar, and particularly only one busbar, provided thereon, which can be located at an edge of the solar cell piece.

In some implementations, an adhesive 17, such as an electrically conductive adhesive, can be provided to connect to solar cell pieces in the overlapping region. According to some embodiments, which can be combined with other embodiments described herein, the apparatus of the present disclosure includes an adhesive application device configured to apply the adhesive 17 to the solar cell or the solar cell pieces thereof, before the two or more solar cell pieces are positioned on the support device. Two solar cell pieces can be overlapped with the adhesive 17 being provided at one solar cell piece of the two solar cell pieces such that the two solar cell pieces can be electrically and mechanically connected to each other. For example, the adhesive can be in a substantially liquid form when the adhesive is applied to a solar cell or solar cell piece.

According to some embodiments, the adhesive application device can be configured to apply the adhesive 17 on at least a portion of the conductive line pattern, such as the busbars, of the solar cell or the solar cell pieces thereof. In some implementations, the adhesive is applied before the solar cell is divided into the two or more solar cell pieces. In other implementations, the adhesive is applied to the solar cell piece(s) after the solar cell has been divided into the two or more pieces. According to some embodiments, the adhesive is selected from the group consisting of solder, silver paste, silicone-based electrically conductive adhesive, and epoxy-based electrically conductive adhesive. When pieces have been overlapped, for example, during assembly of the solar cell arrangement, a drying process can be performed to dry the adhesive. In some implementations, the drying process can include a heating of the overlapping region of the two solar cell pieces using, for example, a heater such as an infrared heater.

Each solar cell piece can have a first extension and a second extension which may be defined in a plane essentially parallel to the frontside and/or backside of the solar cell piece. The first extension can be larger than the second extension. The first extension and the second extension can be defined at, or by, edges of the solar cell piece. The first extension can also be referred to as “major extension” or “long edge” and the second extension can be referred to as “minor extension” or “small edge”. According to some embodiments, the first extension can be defined substantially parallel to a busbar and/or substantially perpendicular to fingers of the solar cell piece and the second extension can be defined substantially perpendicular to the busbar and/or substantially parallel to the fingers.

The positioning device can be configured to selectively or individually adjust the overlap O of adjacent solar cell pieces based on a predetermined length of the solar cell arrangement. The overlap O can be defined along the second extension, e.g., parallel to the short edge of the solar cell piece and/or perpendicular to the length extension of the busbar. Specifically, the overlap O can be defined essentially parallel to the length extension of the solar cell arrangement 20. The overlap can be less than 2 mm, specifically less than lmm, and more specifically less than 0.5 mm e.g. along the length extension of the solar cell arrangement 20. By selectively adjusting the overlap O for each pair of adjacent solar cell pieces, a well-defined length of the solar cell arrangement can be provided.

The overlap can be adjusted to provide an essentially constant distance D between edges of the adjacent solar cell pieces. The distance is defined between an edge 12a of the second solar cell piece 12, wherein the edge 12a overlaps the first solar cell piece 11, and an edge 11a of the first solar cell piece 11, wherein the edge 11a does not overlap the second solar cell piece 12. The edges can be essentially parallel to each other, e.g., along the first extension of the solar cell pieces. The edges can be the long edges of the solar cell pieces.

The distance D may correspond to a portion of the first solar cell piece 11 along the second extension which is not covered by the second solar cell piece 12. For example, the edges are same-side edges of the solar cell pieces, such as left-side edges or right-side edges. FIG. 2A exemplarily illustrates the distance D defined between the right-side edges of the first solar cell piece 11 and the second solar cell piece 12. By providing the essentially constant distance D for all pairs of adjacent solar cell pieces of the solar cell arrangement, the solar cell arrangement can have a well-defined length.

FIG. 2B shows a schematic view of overlapping solar cell pieces according to the further embodiments described herein. Exemplarily three solar cell pieces are shown, namely a first solar cell piece 11, a second solar cell piece 12 and a third solar cell piece 12′. The first solar cell piece 11, the second solar cell piece 12, and the third solar cell piece 12′ are (edge) pieces of a pseudo-square solar cell having rounded edges (“pseudo-square pieces”). FIG. 2B exemplarily illustrates the distance D defined between the left-side edges of the pairs of adjacent solar cell pieces.

FIG. 3 shows a schematic top-view of a separation device 110 according to embodiments described herein.

The separation device 110 is configured to separate a solar cell 10 into two or more solar cell pieces. In particular, the separation device 110 can create smaller cells (solar cell pieces or solar cell elements) starting from the (big) solar cell. According to some embodiments, which can be combined with other embodiments described herein, the separation device 110 includes, or is, a cleaving device configured to mechanically contact the solar cell 10 to divide the solar cell 10. In some implementations, the cleaving device includes a moveable body and a contact element 114 fixed to the moveable body. The contact element 114 can be a blade or an element with a sharp tip configured to contact the solar cell 10 for cleaving and dividing the solar cell 10. In some implementations, the moveable body can be configured to move the contact element 114 towards the solar cell, for example, in a quick motion, in order to provide a sharp dividing line at the solar cell 10.

The separation device 110 may provide solar cell pieces having slightly different dimensions due to manufacturing tolerances, misalignment of the solar cell 10 to be cleaved, and the like. The embodiments of the present disclosure can compensate for the different dimensions such that solar cell arrangements having a well-defined length can be manufactured.

In some implementations, the apparatus of the present disclosure, and particularly the separation device 110, includes a support arrangement having a first support element 116 and optionally a second support element 117. In some implementations, the first support element 116 and/or the second support element 117 can be belt conveyors configured for conveying the solar cell 10 and/or solar cell pieces. The first support element 116 can be configured such that the solar cell 10 protrudes over an edge of the first support element 116 during the separation process. The solar cell piece that has been separated from the solar cell 10 can be collected or caught by the second support element 117, which can be offset with respect to the first support element 116, for example, in the vertical direction. For example, the solar cell piece can fall onto the second support element 117 when the solar cell piece has been separated from the solar cell 10.

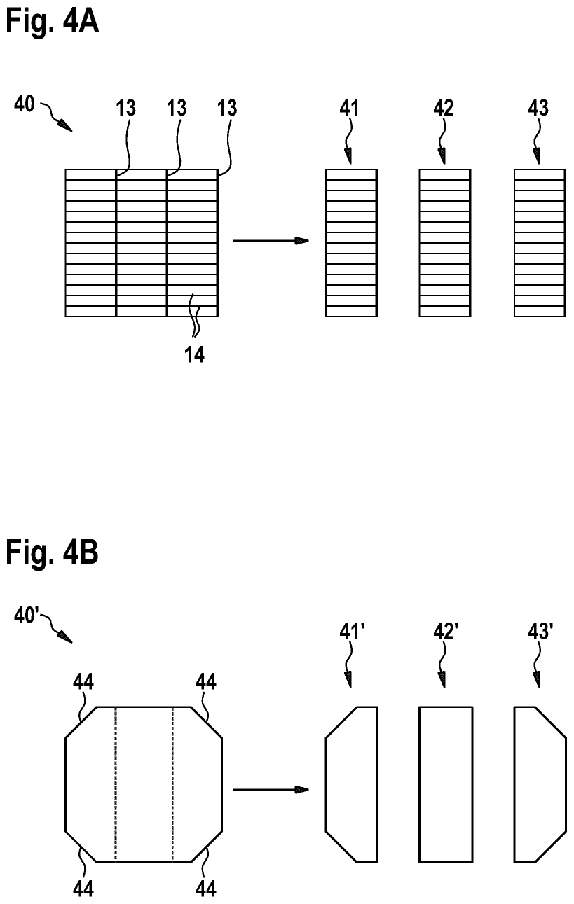

FIGS. 4A and B show schematic views of a full-square solar cell 40 and a pseudo-square solar cell 40′, respectively, according to embodiments described herein.

The full-square solar cell 40 can be, for example, a quadratic multi crystalline wafer cut from silicon ingots. The full-square solar cell 40 having fingers 14 and busbars 13 provided thereon can be cleaved into a plurality of pieces, such as the three pieces 41, 42, and 43 which are exemplarily illustrated in FIG. 4A.

The pseudo-square solar cell 40′ can be a squared wafer with rounded edges 44 cut from monocrystalline silicon ingots. In comparison with the full-square solar cell 40, the pseudo-square solar cell 40′ can be beneficial in that less waste is produced during the manufacturing process. The pseudo-square solar cell 40′ can be cleaved into a plurality of pieces, such as the three pieces 41′, 42′, and 43′ exemplarily illustrated in FIG. 4B.

According to some embodiments, which can be combined with other embodiments described herein, the solar cells, such as the full-square solar cell 40 and/or pseudo-square solar cell 40′, can be separated or divided at positions adjacent to the busbars 13 of the respective solar cell. In other words, each solar cell piece can have a busbar, and particularly only one busbar, provided thereon, which can be located at an edge of the solar cell piece.

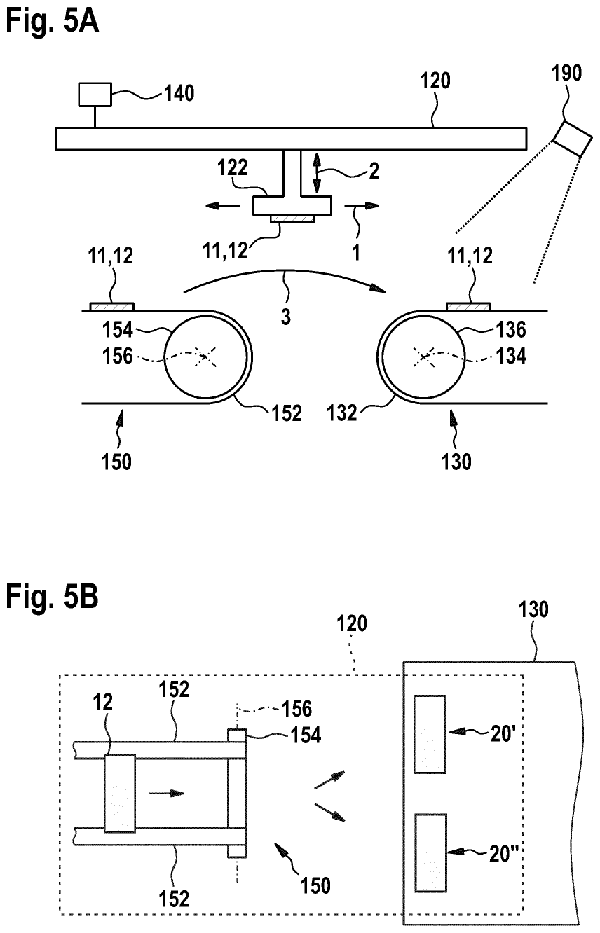

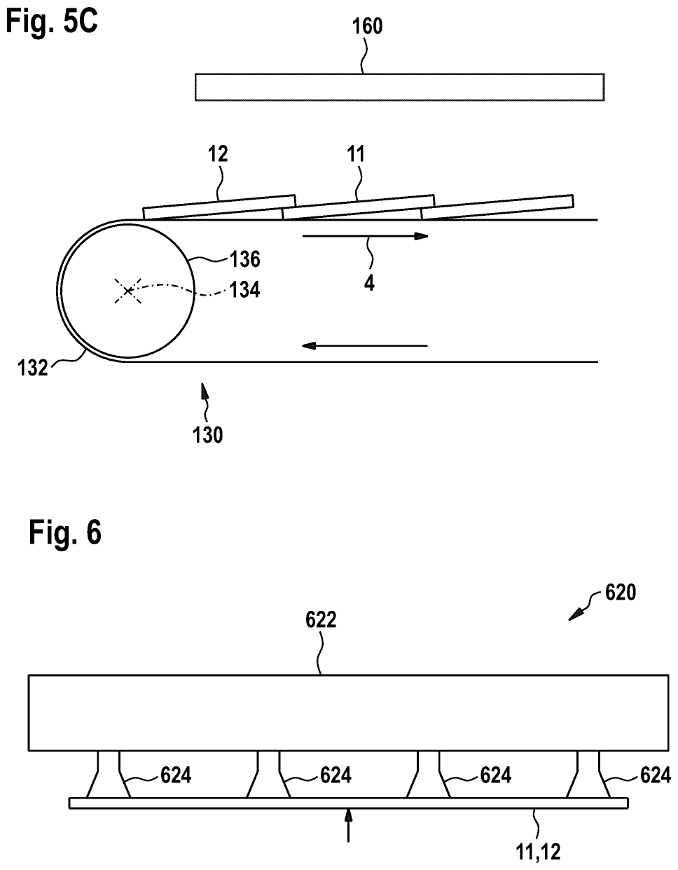

FIG. 5A shows a schematic side view of an apparatus for the manufacture of at least one solar cell arrangement according to further embodiments described herein. FIG. 5B shows a schematic top view of the apparatus and FIG. 5C shows a schematic view of overlapping solar cell pieces on a support device according to embodiments described herein.

According to some embodiments, which can be combined with other embodiments described herein, the apparatus, and particularly the positioning device 120, is configured for the manufacture of at least two solar cell arrangements, such as a first solar cell arrangement 20′ and a second solar cell arrangement 20″. The positioning device 120 can be configured for positioning the solar cell pieces e.g. provided by the separation device on the support device 130 for a parallel assembling of the at least two solar cell arrangements. In some implementations, the positioning device 120 is configured for positioning two or more solar cell pieces on the support device 130 for forming the first solar cell arrangement 20′ and for positioning two or more further solar cell pieces on the support device 130 for forming the second solar cell arrangement 20′.

According to some embodiments, which can be combined with other embodiments described herein, the apparatus includes a transport device 150 configured for transportation of the solar cell pieces of the solar cell(s), such as the first solar cell piece 11 and the second solar cell piece 12. The transport device 150 can include, or be, a belt conveyor having a roller 154 rotatable around a first rotational axis 156 and one or more first belts 152 provided on the roller 154. In some implementations, the transport device 150 can have two or more belts arranged in parallel and with gaps provided between the two or more belts.

According to some embodiments, the support device 130 of the apparatus for the manufacture of a solar cell arrangement according to the embodiments described herein can include, or be, a belt conveyor. The support device 130, e.g., the belt conveyor, can be configured to support, fix and transport the solar cell arrangement(s), such as the first solar cell arrangement 20′ and the second solar cell arrangement 20″. In particular, the support device 130 can be configured for transportation of the solar cell arrangement(s) in a transport direction 4 (see FIG. 5C), which can be a substantially horizontal direction.

The belt conveyor constituting the support device 130 can include a roller 136 rotatable around a second rotational axis 134 and one or more second belts 132 provided on the roller 136. In some implementations, the support device 130 can have two or more belts arranged in parallel and with gaps provided between the two or more belts. For example, each belt of the two or more belts can be configured to support (only) one solar cell arrangement. According to some embodiments, which can be combined with other embodiments described herein, the support device 130 includes, or is, at least one of an electrostatic chuck and a vacuum chuck.

The positioning device 120 can be configured for moving or transferring the solar cell pieces of the solar cell from, for example, the transport device 150 to the support device 130 (indicated with reference numeral 3). For example, the positioning device 120 can sequentially grip or pick up the solar cell pieces from the transport device 150, move the solar cell pieces to the support device 130, optionally align the solar cell pieces, and release the solar cell pieces in a predetermined position. In particular, the positioning device 120 can be configured to arrange the solar cell pieces in an overlapping manner to form the solar cell arrangement, such as the first solar cell arrangement 20′ and the second solar cell arrangement 20′, with the individually adjusted overlap and/or constant pitch. While the solar cell arrangement(s) is/are assembled on the support device 130, the support device 130 having the (partially) assembled solar cell arrangement(s) positioned thereon can continuously move in the transport direction 4. A continuous manufacturing process can be provided.

According to some embodiments, which can be combined with other embodiments described herein, the positioning device 120 includes a gripper 122 configured to grip and hold a solar cell piece. The gripper 122 can be selected from the group consisting of vacuum grippers, mechanical grippers, electrostatic grippers, electrodynamic grippers, and any combination thereof. Embodiments of the gripper 122 are further explained with respect to FIG. 6.

In some implementations, the positioning device 120 is movable in at least one of a first direction 1 and a second direction 2. The first direction 1 can be a substantially horizontal direction. The second direction 2 can be a substantially vertical direction. The positioning device 120 can be movable sequentially or simultaneously in at least one of the first direction 1 and the second direction 2. The solar cell piece held by the positioning device 120 can be moved to the support device 130 for the assembly of a solar cell arrangement, such as the first solar cell arrangement 20′ and/or the second solar cell arrangement 20′, by the movement in the first direction 1 and the second direction 2.

For example, the positioning device 120 can move in the second direction 2, for example, upwards, to pick up the solar cell piece from the transport device 150. The positioning device 120 can then move in the first direction 1, for example, forwards, to move the solar cell piece from the transport device 150 to the support device 130. The positioning device 120 can move in the second direction 2, for example, downwards, to place the solar cell piece on the support device 130. The positioning device 120 can then move in the second direction 2 and the first direction 1, for example, back to the transport device 150 to pick up another solar cell piece from the transport device 150. It is to be understood that the movement in the first direction 1 can be a movement in a forward direction and a backward direction. Likewise, the movement in the second direction 2 can be a movement in an upward direction and a movement in a downward direction.

The term “vertical direction” is understood to distinguish over “horizontal direction”. That is, the “vertical direction” relates to a substantially vertical movement, wherein a deviation of a few degrees, e.g. up to 5° or even up to 10°, from an exact vertical direction is still considered as a “substantially vertical direction”. The vertical direction can be substantially parallel to the force of gravity.

According to some embodiments, the apparatus includes a controller 140 configured to control the positioning device 120. In particular, the controller 140 can control a movement of the positioning device 120 to move a solar cell piece to assemble the solar cell arrangement(s) with the selectively adjusted overlap and/or the constant pitch. For example, the controller 140 can control the positioning device 120 to move the solar cell piece to either the first solar cell arrangement 20′ or the second solar cell arrangement 20′ based on one or more properties (e.g., geometric and/or physical properties) of the piece, such as geometric shape, electrical properties, optical properties, printing quality, and any combination thereof.

In the example of FIG. 5C, the positioning device 120 is configured to overlap the second solar cell piece 12 on the first solar cell piece 11 already provided on the support device 130. The apparatus, and particularly the positioning device 120, can be configured for alignment of the solar cell piece held by the positioning device 120, such as the second solar cell piece 11, before the solar cell piece is put on the support device 130 e.g. to be overlapped with another solar cell piece, such as the first solar cell piece 11. In some implementations, the controller 140 is configured to control the positioning device 120 to perform the alignment. The apparatus, and particularly the positioning device 120, can be configured for an alignment of the solar cell piece to selectively adjust the overlap of adjacent solar cell pieces based on a predetermined length of the solar cell arrangement and/or to provide the essentially constant distance (or pitch) between edges of the adjacent solar cell pieces.

According to some embodiments, which can be combined with other embodiments described herein, the apparatus is configured to determine a position and/or an orientation of at least one solar cell piece of the two solar cell pieces which are to be overlapped. For example, the apparatus is configured to determine a position and/or orientation of both solar cell pieces, such as the first solar cell piece 11 and the second solar cell piece 12, for alignment. The apparatus can use information acquired by an inspection system 190 which can include, for example, a camera configured to detect a position and/or orientation of the solar cell piece, for example, held by the positioning device 120.

According to some embodiments, which can be combined with other embodiments described herein, the apparatus further includes the inspection device 190 configured to detect one or more structural features of at least one solar cell piece, such as the first solar cell piece 11 and/or the second solar cell piece 12. Specifically, the inspection device 190 can be configured to detect one or more structural features of a solar cell piece, such as the first solar cell piece 11, before the solar cell piece and another solar cell piece, such as the second solar cell piece 12, are overlapped. In some implementations, the positioning device 120 can be configured to selectively adjust the overlap and/or provide the essentially constant distance between the edges of the adjacent solar cell pieces based on the one or more structural features detected by the inspection device 190. The apparatus, and particularly the controller 140 and/or the inspection device 190, can be configured to determine a position and/or orientation of the first solar cell piece 11 and/or the second solar cell piece 12 based on the one or more structural features detected by the inspection device 190.

According to some embodiments, which can be combined with other embodiments described herein, the inspection device 190 includes one or more sensors configured to detect the one or more structural features, which can be one or more edges and/or corners of the solar cell piece. The inspection device 190, and particularly the one or more sensors, can be positioned on (only) one side of the solar cell piece and/or the solar cell arrangement, e.g., above the solar cell piece and/or solar cell arrangement as it is illustrated in the example of FIG. 5A. To the contrary, in systems other than described herein and which use a constant overlap, sensors are provided on both sides of the string, i.e., above and below the string. The embodiments of the present disclosure can simplify a configuration of the (metrology or) inspection system because the sensor(s) can be placed on only one side rather than two opposite side.

According to some embodiments, which can be combined with other embodiments described herein, the inspection device 190 is configured to detect one or more first structural features of the first solar cell piece 11 and/or one or more second structural features of the second solar cell piece 120. The positioning device 120 can be configured to at least one of: selectively adjust the overlap and provide the essentially constant distance between the edges of the adjacent solar cell pieces based on the one or more first structural features and/or the one or more second structural features detected by the inspection device 190.

According to some embodiments, which can be combined with other embodiments described herein, the one or more structural features of a respective solar cell piece, such as the one or more first structural features and/or the one or more second structural features, are selected from the group including (or consisting of) an edge of the solar cell piece, a portion of an edge of the solar cell piece, a pattern (e.g. a conductive line pattern such as fingers and/or busbars) on the solar cell piece, alignment marks on the solar cell piece, and any combination thereof.

In some implementations, the positioning device 120 is movable a plane, such as a substantially horizontal plane. Such a movement can also be referred to as “0 movement”. For example, the positioning device 120 can be configured to adjust or align an angular orientation of a solar cell piece held by the positioning device 120 in the plane. The angular orientation of the solar cell piece can be aligned, for example, with respect to the support device 130 and/or another solar cell piece on the support device 130 with which the solar cell piece held by the positioning device 120 is to be overlapped. The solar cell arrangement can be assembled with a variable overlap to provide solar cell arrangements of a constant length.

According to some embodiments, the positioning device 120 can be configured to rotate the solar cell piece around a substantially vertical rotational axis e.g. by about 180°. In particular, edge pieces of pseudo-square solar cells can be brought into similar orientations. For example, one edge piece (e.g., the front or leading edge piece) of the pseudo-square solar cell is not rotated by about 180° and the other edge piece (e.g., the back or trailing edge piece) of the pseudo-square solar cell is rotated by about 180° such that the geometric shapes of the edge pieces are equally oriented or aligned as it is for instance illustrated in FIG. 2B.

According to some embodiments, the positioning device 120 is tiltable, for example, with respect to the first direction 1 and/or a horizontal plane. For example, the positioning device 120 can tilt the solar cell piece held by the positioning device 120 to align an orientation of the solar cell piece with respect to another solar cell piece on the support device 130 to provide the adjusted overlap and/or constant edge distance. In particular, the backside or backside plane of the solar cell piece held by the positioning device 120 can be oriented to be substantially parallel to a frontside or frontside plane of the other solar cell piece on the support device 130. In some implementations, the positioning device 120 is configured to align a backside contact of the solar cell piece with respect to a frontside contact, such as a busbar, of another solar cell piece on the support device 130 such that an electrical contact between the backside contact and the frontside contact can be established, for example, with an adhesive provided therebetween.

According to some embodiments, which can be combined with other embodiments described herein, the apparatus further includes a heating device 160, for example, at or above the support device 130. The heating device 160 can be configured to heat at least one of the solar cell arrangements on the support device 130, such as the first solar cell arrangement 20′ and/or the second solar cell arrangement 20′. The heating device 160 can be selected from the group consisting of conduction heaters (e.g., hot plates), convective heaters, resistive heaters, infrared heaters, lamp heaters, hot air heaters, and any combination thereof.

FIG. 6 shows a schematic view of a positioning device 620 according to embodiments described herein.

According to some embodiments, which can be combined with other embodiments described herein, the positioning device 620 includes one or more grippers 622 configured to grip and hold a solar cell piece, such as the first solar cell piece 11 and/or the second solar cell piece 12. The one or more grippers 622 can be selected from the group consisting of vacuum grippers, mechanical grippers, electrostatic grippers, electrodynamic grippers, and any combination thereof. The vacuum can use a suction force to hold the solar cell piece at the gripper. The mechanical gripper can use mechanical devices, such as clamps, to hold the solar cell piece at the gripper. The electrostatic grippers and electrodynamic grippers can use an electrostatic force and an electrodynamic force, respectively, to hold the solar cell piece at the gripper.

In some implementations, at least one gripper, and particularly each gripper, of the one or more grippers 622 can include one or more gripper elements 624. For example, the gripper can include two or more, such as three, four, five or six gripper elements configured for contacting and gripping a solar cell piece. For example, the one or more gripper elements 624 can be suction cups configured to provide an under-pressure at a surface of the solar cell piece to hold the piece that includes the one or more gripper elements 624.

According to some embodiments, each gripper of the one or more grippers 622 is configured to hold and move one solar cell piece. In further embodiments, each gripper of the one or more grippers 622 is configured to simultaneously hold and move two or more solar cell pieces.

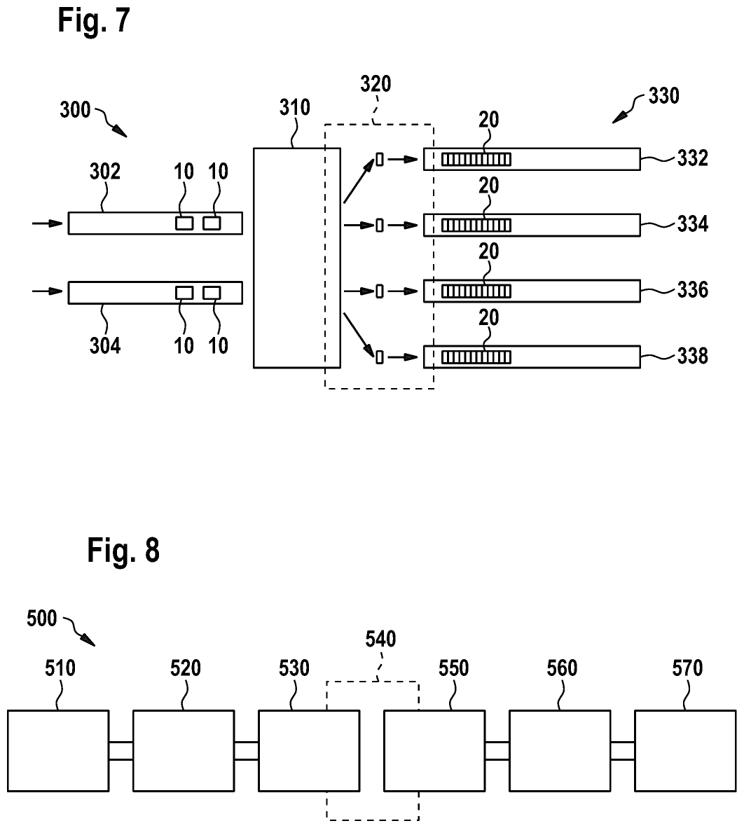

FIG. 7 shows a schematic view of an apparatus 300 for the manufacture of at least two solar cell arrangements, such as shingled solar cells, according to an embodiment described herein.

According to some embodiments, which can be combined with other embodiments described herein, the apparatus 300 can include one or more input conveyors, such as a first input conveyor 302 and a second input conveyor 304, configured to input a plurality of solar cells into the separation device 310. The one or more input conveyors can be parallel lanes for simultaneously inputting a plurality of solar cells into the separation device 310. The one or more input conveyors can be belt conveyors. According to some embodiments, the transport device described with respect to FIGS. 5A and 5B can be provided by the one or more input conveyors.

The positioning device 320 is configured to position the solar cell pieces provided by the separation device 310 on the support device 330 e.g. for the parallel assembling of the at least two solar cell arrangements. The overlap of adjacent solar cell pieces of the at least two solar cell arrangements is individually adjusted to provide essentially constant string lengths.

According to some embodiments, which can be combined with other embodiments described herein, the support device 330 can have two or more support units arranged in parallel. The two or more support units can be separated from each other. Each support unit of the two or more support units can be configured to support a respective solar cell arrangement of the at least two solar cell arrangements. For example, a first support unit 332 can be configured to support the first solar cell arrangement and a second support unit 334 can be configured to support the second solar cell arrangement. The support device 330 can include further support units, such as a third support unit 336 and the fourth support unit 338 configured to support further solar cell arrangements. However, the present disclosure is not limited thereto and one single support unit, such as one single belt, can be provided on which the at least two solar cell arrangements can be assembled in parallel.

According to some embodiments, the support device 330 includes the at least one belt conveyor, wherein the at least one belt conveyor includes two or more belt conveyor spaced apart from each other. For example, a first belt conveyor is configured to support the first solar cell arrangement and a second belt conveyor spaced apart from the first belt conveyor is configured to support the second solar cell arrangement. In some implementations, the two or more support units are belt conveyors arranged in parallel. For example, the first support unit 332 is the first belt conveyor, the second support unit 334 is the second belt conveyor, the third support unit 336 is a third belt conveyor, and the fourth support unit 338 is a fourth belt conveyor. The first to fourth belt conveyors can be arranged in parallel.

In some implementations, a movement of the support device 330 provided by the belt conveyor and a movement of the at least one positioning device 320 are synchronized or correlated with each other. For example, a movement of the first input conveyor 302, a cleaving process of the solar cells inputted via the first input conveyor 302, an operation of the positioning device 320, and a movement of the first support unit 332 and the second support unit 334 are synchronized or coordinated. Likewise, a movement of the second input conveyor 304, a cleaving process of the solar cells inputted via the second input conveyor 304, an operation of the positioning device 320, and a movement of the third support unit 336 and the fourth support unit 338 are synchronized or coordinated.

FIG. 8 shows a schematic view of a system 500 for the manufacture of a solar cell arrangement according to embodiments described herein. The system 500 can be part of, or constitute, a production line for shingled solar cells.

The system 500 includes the apparatus for the manufacture of a solar cell arrangement according to the embodiments described herein. The system 500 further includes a production tool 510 for the manufacture of a plurality of solar cells, the separation device 530 configured to separate the plurality of solar cells into solar cell pieces, the positioning device 540, and the support device 550 on which the solar cell arrangement(s) is/are assembled.

In some implementations, the production tool 510 includes one or more printing devices configured for printing one or more conductive lines on solar cell substrates used in the manufacture of the plurality of solar cells. The one or more conductive lines are selected from fingers and busbars. The one or more printing devices can be configured for double printing of the one or more conductive lines. Specifically, the one or more printing devices can be configured for double printing of at least one of the fingers and busbars.

According to some embodiments, the system 500, and particularly the apparatus, includes an adhesive application device 520 configured to apply an adhesive to the solar cell before the solar cell is separated into the two or more solar cell pieces. The adhesive is applied to portions of the solar cell corresponding to an overlapping region between two adjacent solar cell pieces that are arranged on the support device 550 in the overlapping manner. According to some embodiments, the adhesive application device 520 can be configured to apply the adhesive on at least a portion of the conductive line pattern, such as the busbars, of the solar cell.

According to some embodiments, which can be combined with other embodiments described herein, the separation device 530 includes at least one solar cell perforation device. For example, the at least one solar cell perforation device includes, or is, a laser. For example, the at least one solar cell perforation device can be configured to perforate the solar cell before the solar cell is separated into the two or more solar cell pieces.

In some implementations, the system 500 further includes a heating device 560, for example, subsequent to, or above, the support device 550 of the apparatus. An embodiment of the heating device 560 is described with respect to FIG. 5C. In particular, the heating device 560 is configured to heat at least one of the solar cell arrangements to dry the adhesive in the overlapping region between two adjacent solar cell pieces. The heating device 560 can be selected from the group consisting of conduction heaters (e.g., hot plates), convective heaters, resistive heaters, infrared heaters, lamp heaters, hot air heaters, and any combination thereof.

According to some embodiments, which can be combined with other embodiments described herein, the system 500 includes a sorting device 570 configured for sorting the at least two solar cell arrangements, such as the first solar cell arrangement and the second solar cell arrangement, based on a quality determination of the at least two solar cell arrangements. For example, solar cell arrangements which are defective or have a low quality can be discarded. Optionally, defective solar cell arrangements can undergo a reworking or repair process, for example, to replace defective or low-quality solar cell pieces.

FIG. 9 shows a flow chart of a method 1000 for the manufacture of a solar cell arrangement, such as a shingled solar cell, according to embodiments described herein. The method 1000 can use the apparatuses and systems according to the embodiments described herein. Likewise, the apparatuses and systems of the present disclosure can be configured to implement the method 1000.

The method 1000 includes in block 1100 a positioning of a first solar cell piece on a support device and in block 1200 an overlapping of a second solar cell piece with the first solar cell piece. An overlap of the first solar cell piece and the second solar cell piece can be determined based on a predetermined length of the solar cell arrangement. Optionally or alternatively, an essentially constant distance or pitch is provided between an edge of the second solar cell piece overlapping the first solar cell piece and an edge of the first solar cell piece not overlapping the second solar cell piece.

According to some embodiments, which can be combined with other embodiments described herein, the method 1000 further includes a detecting of one or more structural features of at least one of the first solar cell piece and the second solar cell piece before overlapping the second solar cell piece on the first solar cell piece. In some implementations, the method 1000 includes an aligning of the first solar cell piece and the second solar cell piece before the overlapping of the first solar cell piece and the second solar cell piece to provide the adjusted overlap and/or the constant distance or pitch.

The method 100 can further include a separating of each solar cell of one or more solar cells into two or more solar cell pieces, and a forming of at least a first solar cell arrangement and a second solar cell arrangement from the two or more solar cell pieces. Each solar cell piece of the two or more solar cell pieces can be allocated to the first solar cell arrangement or the second solar cell arrangement based on one or more geometric and/or physical properties of the solar cell piece. In some implementations, the one or more solar cells are selected from the group consisting of full-square solar cells and pseudo-square solar cells.

According to some embodiments, which can be combined with other embodiments described herein, each solar cell of the one or more solar cells is separated into two, three, four, five, six, or more solar cell pieces. The number of solar cell pieces into which each solar cell is separated can be selected according to at least one of a type of the solar cell (e.g., pseudo-full square or full-square), a number of solar cell arrangements that are to be assembled in parallel, and a configuration of the support device (e.g., one single belt or multiple support units having separate belts).

In some implementations, the method 1000 further includes a gripping of the two or more solar cell pieces and a positioning of the two or more solar cell pieces on the support device to form the solar cell arrangement, such as the first solar cell arrangement and the second solar cell arrangement. The gripping can be performed using the positioning device according to the present disclosure. In particular, a suction force provided by a vacuum gripper can be used to pick up the solar cell piece.

According to some embodiments, the method 1000 further includes an applying of an adhesive to the solar cell or the two or more solar cell pieces before positioning the two or more solar cell pieces on the support device. In particular, the adhesive can be applied in the overlapping region of two adjacent solar cell pieces. According to some embodiments, the adhesive is an electrically conductive adhesive selected from the group consisting of solder, silver paste, and electrically conductive silicone adhesive. In some implementations, the method 1000 can include a drying of the adhesive while the two or more pieces are fixed to, or held on, the support device. The drying can be performed using the heating device, such as an infrared heater. The heating device can be provided at the support device and can heat the solar cell arrangement while the solar cell arrangement is moved or transported below the heating device.

According to embodiments described herein, the method for the manufacture of a solar cell arrangement can be conducted using computer programs, software, computer software products and the interrelated controllers, which can have a CPU, a memory, a user interface, and input and output devices being in communication with the corresponding components of the apparatus for processing a large area substrate.

The embodiments of the present disclosure individually adjusts a relative positioning of two adjacent solar cell pieces. In particular, an overlap of adjacent solar cell pieces is individually adjusted and/or an essentially constant distance between edges of the adjacent solar cell pieces is provided. Solar cell arrangements having a predetermined length, i.e., a defined length or set length, can be manufactured. A difference in string lengths depending on shingle dimensions can be reduced or even avoided.

While the foregoing is directed to embodiments of the disclosure, other and further embodiments of the disclosure may be devised without departing from the basic scope thereof, and the scope thereof is determined by the claims that follow.

1. An apparatus for manufacture of a solar cell arrangement having two or more overlapping solar cell pieces, comprising:
a positioning device configured to selectively adjust an overlap of adjacent solar cell pieces based on a predetermined length of the solar cell arrangement.

2. The apparatus of claim 1, wherein the positioning device is configured to provide an essentially constant distance between edges of the adjacent solar cell pieces, wherein the distance is defined between an edge of a second solar cell piece overlapping a first solar cell piece and an edge of the first solar cell piece not overlapping the second solar cell piece.

3. An apparatus for manufacture of a solar cell arrangement having two or more overlapping solar cell pieces, comprising:
a positioning device configured to provide an essentially constant distance between edges of adjacent solar cell pieces, wherein the distance is defined between an edge of a second solar cell piece overlapping a first solar cell piece and an edge of the first solar cell piece not overlapping the second solar cell piece.

4. The apparatus of claim 3, wherein the positioning device is configured to selectively adjust an overlap of the adjacent solar cell pieces based on a predetermined length of the solar cell arrangement.

5. The apparatus of claim 1, wherein the positioning device is configured to position two or more solar cell pieces on a support device such that the adjacent solar cell pieces overlap.

6. The apparatus of claim 1, further including an inspection device configured to detect one or more structural features of a first solar cell piece before the first solar cell piece and a second solar cell piece are overlapped.

7. The apparatus of claim 6, wherein the positioning device is configured for at least one of:
selectively adjust the overlap based on the one or more structural features detected by the inspection device, and
provide the essentially constant distance between the edges of the adjacent solar cell pieces based on the one or more structural features detected by the inspection device.

8. The apparatus of claim 6, wherein the positioning device is configured to overlap the first solar cell piece with the second solar cell piece provided on the support device, or wherein the positioning device is configured to overlap the second solar cell piece with the first solar cell piece provided on the support device.

9. The apparatus of claim 6, wherein the inspection device is configured to detect one or more first structural features of the first solar cell piece and one or more second structural features of the second solar cell piece, and wherein the positioning device is configured to at least one of:
selectively adjust the overlap based on the one or more first structural features and the one or more second structural features, and
provide the essentially constant distance between the edges of the adjacent solar cell pieces based on the one or more first structural features and the one or more second structural features.

10. The apparatus of claim 6, wherein the inspection device is configured to detect one or more edges of a solar cell piece as the one or more structural features of the solar cell piece.

11. The apparatus of claim 6, wherein the inspection device is provided on one side of the solar cell arrangement.

12. A system for manufacture of a solar cell arrangement, comprising:
an apparatus for manufacture of a solar cell arrangement having two or more overlapping solar cell pieces, the apparatus comprising:
a positioning device configured to selectively adjust an overlap of adjacent solar cell pieces based on a predetermined length of the solar cell arrangement;
a production tool for manufacturing a plurality of solar cells; and
a separation device configured to separate the plurality of solar cells into solar cell pieces.

13. A method for assembling a solar cell arrangement, comprising:
positioning a first solar cell piece on a support device; and
overlapping a second solar cell piece with the first solar cell piece, wherein an overlap of the first solar cell piece and the second solar cell piece is determined based on a predetermined length of the solar cell arrangement.

14. A method for assembling a solar cell arrangement, comprising:
positioning a first solar cell piece on a support device; and
overlapping a second solar cell piece with the first solar cell piece, wherein an essentially constant distance is provided between an edge of the second solar cell piece overlapping the first solar cell piece and an edge of the first solar cell piece not overlapping the second solar cell piece.

15. The method of claim 13, further including at least one of:
detecting one or more structural features of at least one of the first solar cell piece and the second solar cell piece before overlapping the second solar cell piece; and
aligning the first solar cell piece and the second solar cell piece before overlapping the first solar cell piece and the second solar cell piece.

16. The apparatus of claim 3, wherein the positioning device is configured to position two or more solar cell pieces on a support device such that the adjacent solar cell pieces overlap.

17. The apparatus of claim 3, further including an inspection device configured to detect one or more structural features of a first solar cell piece before the first solar cell piece and a second solar cell piece are overlapped.

18. The apparatus of claim 7, wherein the positioning device is configured to overlap the first solar cell piece with the second solar cell piece provided on the support device, or wherein the positioning device is configured to overlap the second solar cell piece with the first solar cell piece provided on the support device.

19. The apparatus of claim 7, wherein the inspection device is configured to detect one or more first structural features of the first solar cell piece and one or more second structural features of the second solar cell piece, and wherein the positioning device is configured to perform at least one of:
selectively adjust the overlap based on the one or more first structural features and the one or more second structural features, and
provide the essentially constant distance between the edges of the adjacent solar cell pieces based on the one or more first structural features and the one or more second structural features.

20. A system for manufacture of a solar cell arrangement, comprising:
an apparatus for manufacture of a solar cell arrangement having two or more overlapping solar cell pieces, comprising:
a positioning device configured to provide an essentially constant distance between edges of adjacent solar cell pieces, wherein the distance is defined between an edge of a second solar cell piece overlapping a first solar cell piece and an edge of the first solar cell piece not overlapping the second solar cell piece;
a production tool for manufacturing a plurality of solar cells; and
a separation device configured to separate the plurality of solar cells into solar cell pieces.

21. A solar cell arrangement comprising a plurality of overlapping solar cell pieces, wherein at least two overlaps (0) of the overlapping solar cell pieces in the solar cell arrangement are different.

22. The solar cell arrangement of claim 21, wherein the plurality of overlapping solar cell pieces have an essentially constant distance (D) between edges of adjacent solar cell pieces, wherein the essentially constant distance (D) is defined between a second edge of a second solar cell piece and a first edge of a first solar cell piece, the second edge overlapping the first solar cell piece and the first edge not overlapping the second solar cell piece.
